(19) United States
(12) Patent Application Publication
(10) Pub. No.: US 2005/0136285 A1
(43) Pub. Date: Jun. 23, 2005

(54) Multi-layered device and method for making the same

(75) Inventors: Kyle Erik Litz, Ballston Spa, NY (US); Gautam Parthasarathy, Saratoga Springs, NY (US)

Correspondence Address: GENERAL ELECTRIC COMPANY (PCPI);C/O FLETCHER YODER, P. O. BOX 692289, HOUSTON, TX, 77269-2289, US

(73) Assignee: General Electric Company

(21) Appl. No.: 10/742,863

(22) Filed: Dec. 23, 2003

(51) Int. Cl. B32B 9/00; B05D 5/12

(52) U.S. Cl. 428/690; 313/504; 427/66

(57) ABSTRACT

The invention relates to a multi-layered device and a method for making a multi-layered device. The method comprises the steps of determining a desired sequence of two or more polymers in a multi-layered device; for each of the two or more polymers in the desired sequence, identifying a solubility window in a solubility graph, and selecting a solvent based on the solubility window such that the solvent does not dissolve a preceding polymer in the desired sequence; depositing each of the two or more polymers from its selected solvent; and forming a multi-layered device having the two or more polymers in the desired sequence.

### BACKGROUND OF THE INVENTION

The present invention relates generally to the field of electro-optics, and more particularly to a multi-layered device and method for making the same.

Semi-conducting polymers have found wide applications in a number of electro-optic devices such as polymer light emitting devices (PLED's), photovoltaic devices and photo-detectors. A typical PLED comprises a transparent substrate that supports a semi-transparent anode, a cathode and an organic electro-luminescent layer between the anode and the cathode, where the organic electro-luminescent layer comprises one or more polymeric electro-active materials, only one being luminescent. In operation, holes are injected into the device through the anode while electrons are injected into the device through the cathode. The holes and electrons migrate towards each other and recombine in the organic electro-luminescent layer to form an excited energy state, or “exciton,” that relaxes by emission of radiant energy. Additional layers may be present in the PLED. For example, a layer of organic hole transport material, such as poly(ethylene dioxy thiophene)/polystyrene sulfonate (“PEDOT-PSS”), may be provided between the anode and the semi-conducting organic layer to assist injection of holes. A layer of an alkaline earth fluoride salt, such as sodium chloride (NaCl), may be formed between the semi-conducting polymer and the cathode to facilitate electron injection. A typical PLED comprises a single electro-luminescent layer formed as a blend of a hole transport polymer, an electron transport polymer and a light emissive polymer. Alternatively, a single polymer may provide more than one of the functions of hole transport, electron transport and light emission.

Unfortunately, the properties of only a single polymer layer in an electro-optic device are often not sufficient to meet the various demands in opto-electronic applications. Attempts have been made in the prior art to achieve multi-layered devices, where each layer possesses different properties and is selected to play a particular role in an overall function of the device. However, preparation of multiple polymer layers has been problematic due to dissolution of underlying layers in solvents employed for succeeding layers. Further, even if the coating compositions do not dissolve the underlying layer, it is often difficult to achieve a continuous and coalesced film coverage. These and other drawbacks exist in known systems and techniques.

### BRIEF SUMMARY OF THE INVENTION

The present invention is directed to a multi-layered device and method for making the same that overcome these and other drawbacks of known systems and methods.

According to one embodiment, the invention relates to a method for making a multi-layered device comprising the steps of determining a desired sequence of two or more polymers in a multi-layered device; for each of the two or more polymers in the desired sequence, identifying a solubility window in a solubility graph, and selecting a solvent based on the solubility window such that the solvent does not dissolve a preceding polymer in the desired sequence; depositing each of the two or more polymers from its selected solvent; and forming a multi-layered device having the two or more polymers in the desired sequence.

According to another embodiment, the invention relates to a multi-layered device comprising a substrate; a first electrode; a second electrode; and two or more polymers in a predetermined sequence located between the first electrode and the second electrode, wherein each of the two or more polymers is deposited from a solvent that does not dissolve a preceding polymer in the predetermined sequence.

Exemplary embodiments of the invention can enable efficient production of electro-optic devices having a discrete, uniform multi-layer composition. Each layer in the multi-layer composition may be cast from solvent-borne coating compositions whose differential solubility permits discrete film formation with good adhesion and electrical contact. Exemplary embodiments of the present invention can also provide improved brightness, lifetime and efficiency.

### BRIEF DESCRIPTION OF THE DRAWINGS

In order to facilitate a fuller understanding of the present invention, reference is now made to the appended drawings, in which like elements are referenced with like numerals. These drawings should not be construed as limiting the present invention, but are intended to be exemplary only.

FIG. 1 is a flow chart illustrating an exemplary method for making a multi-layered device according to an embodiment of the invention.

FIG. 2 illustrates a solubility graph for a light emissive polymer according to an exemplary embodiment of the invention.

FIG. 3 illustrates a solubility graph for another polymer according to an exemplary embodiment of the invention.

FIG. 4 illustrates the results of a polymer film coating experiment according to an exemplary embodiment of the invention.

FIG. 5 illustrates a cross-sectional view of a multi-layered polymer light emitting device according to an exemplary embodiment of the invention.

FIG. 6 illustrates a solubility graph for a light emissive polymer according to another embodiment of the invention.

FIG. 7 illustrates a solubility graph for a light emissive polymer according to another embodiment of the invention.

### DETAILED DESCRIPTION OF THE INVENTION

Reference will now be made in detail to the present embodiments of the invention, examples of which are illustrated in the accompanying drawings.

Though only polymer light emitting devices and methods for making the same will be described hereinafter, it should be noted that embodiments of the present invention can be applied to all types of multi-layered electro-optic devices, including photovoltaic devices and photo-detectors.

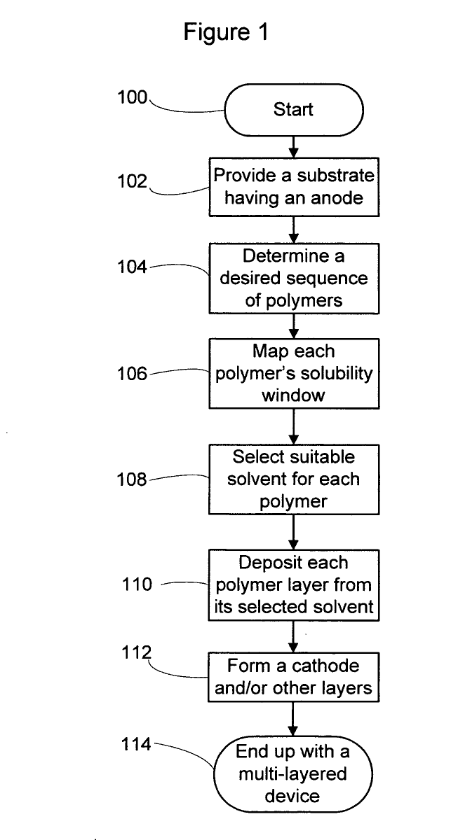

FIG. 1 is a flow chart illustrating an exemplary method for making a multi-layered device according to an embodiment of the invention.

The exemplary method starts at step 100.

At step 102, a substrate having an anode may be provided. According to one embodiment, the substrate may be a transparent piece of material such as glass or flexible plastic. An anode comprising a conductive and transparent metal oxide may be formed on the substrate. A typical anode may be a transparent indium tin oxide (ITO) layer. The anode may be deposited and patterned.

At step 104, a desired sequence of polymers in a multi-layered device may be determined. The types of polymer materials and their stacking sequence in a multi-layered structure may be determined based on desired functions and/or performance of a finished device. For example, for a finished PLED with blue emissions, blue-emissive polyfluorenes (PF's) may be included in the polymer sequence. If improved efficiency is also desired in this blue PLED, additional charge transport polymer layers may be added to either side of the PF layer(s) to assist injection of holes and electrons. According to embodiments of the present invention, different polymer materials with distinct properties may be combined in a multi-layered structure to tailor the functions and/or performance of the final device based on desired specifications or other requirements. A typical multi-layered device according to embodiments of the present invention may comprise two or more polymer layers. According to one embodiment, the layers may comprise two layers of the same polymer separated by another polymer or two layers of the same polymer separated by a blend of the same polymer and another polymer, for example. Or each layer may comprise a different semi-conducting polymer.

At step 106, a solubility window may be mapped for each of the polymers in the multi-layered sequence.

Based on solubility theories, a solubility graph may be constructed for the purpose of solubility analysis. A Hildebrand value, defined as the square root of the cohesive energy density of a solvent, is a known solubility parameter. The Hildebrand value δₜ may be divided into three components to reflect the contribution of a dispersion force, a polarity force and a hydrogen-bonding force. The three corresponding values are called Hansen parameters δ_{d}, δₚ and δₕ, respectively, where δ₁²=δₚ²+δₕ².

Assuming all the solvent materials have the same Hildebrand value, solubility behavior is determined, not by differences in total Hildebrand value, but by the relative amounts of the three component forces that contribute to the total Hildebrand value. This permits comparison based in terms of percentages rather than unrelated sums. Based on this assumption, a triangular graph, called a Teas graph, may be constructed to represent a universe of solvents based on Teas parameters. The Teas parameters f_{d}, fₚ and fₕ, also called fractional parameters, are mathematically derived from Hansen parameters and indicate the percent contribution that each Hansen parameter contributes to the whole Hildebrand value:

$${f}_{d} = 100 \times \frac{{δ}_{d}}{{δ}_{d} + {δ}_{p} + {δ}_{h}}$$

$${f}_{p} = 100 \times \frac{{δ}_{p}}{{δ}_{d} + {δ}_{p} + {δ}_{h}}$$

$${f}_{h} = 100 \times \frac{{δ}_{h}}{{δ}_{d} + {δ}_{p} + {δ}_{h}} .$$

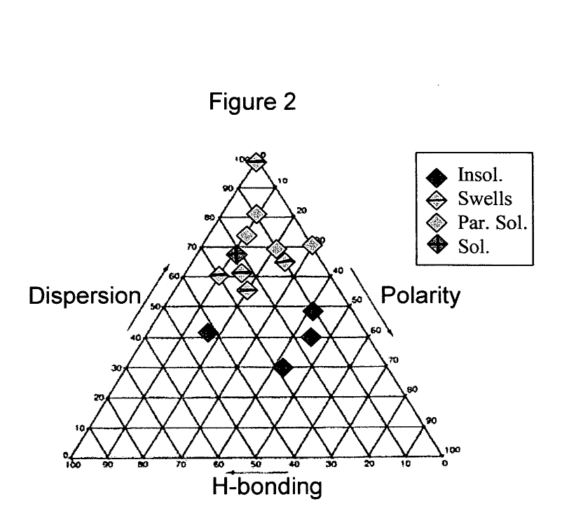

Due to its clarity and ease of use, a Teas graph may be a desirable tool for solubility analysis according to embodiments of the present invention. Examples of Teas graphs are shown in FIGS. 2, 3, 6, and 7. For each of the polymers in the multi-layered sequence, its solubility in a number of solvents may be evaluated and mapped in a Teas graph. The solubility evaluation may be based on theoretical calculation, experiments or existing data. According to one embodiment of the present invention, specific experiments may be designed to test the solubility of a polymer in available solvents and/or their mixtures. The polymer may be soluble, partially soluble, swelling, or insoluble in a particular solvent. The different solubility behaviors of the polymer in the available solvents may be distinctly indicated at the corresponding solvent locations in the Teas graph. As a result, for each polymer, a solid area in the Teas graph may be identified to correspond to solvents in which the polymer is soluble. The edges of this solid area may define a solubility window for this polymer. Within the solubility window, the polymer may be fully soluble, while far away from the solubility window boundary, the polymer may be insoluble. Just outside the boundary, the polymer may be partially soluble or swelling. According to embodiments of the present invention, an insoluble region close to a polymer's solubility window boundary may be identified where the solvents exhibit strong attraction and therefore high adhesion to this polymer. It should also be noted that the solubility window boundary is typically temperature dependent.

At step 108, a suitable solvent may be selected for each polymer. The solubility windows for all the polymers in the multi-layered sequence may be mapped out on a same or similar Teas graph to facilitate comparison. One objective, according to exemplary embodiments of the invention, is to find, for each polymer (“overcoat”), a suitable solvent from which this polymer may be deposited without dissolving a preceding polymer layer (“undercoat”). According to one embodiment of the invention, with respect to a Teas graph, a suitable solvent should lie in the insoluble region of the undercoat where solvent adhesion to the undercoat is strong, yet within a soluble region of the overcoat. As a result, the overcoat polymer may dissolve in this suitable solvent, and the solvent may fully wet the undercoat material but does not dissolve it.

Surface tension may be a further consideration in selecting a suitable solvent. In general, according to exemplary embodiments of the invention, it is desirable for the overcoat to have a lower surface tension than the undercoat so that complete wetting of the undercoat occurs, permitting a complete and conformal coverage. Otherwise the overcoat may have less than desirable adhesion to the undercoat or roll up. According to exemplary embodiments of the invention, an effective selection of surface tensions may be achieved by taking into consideration the dispersion force component δ_{d} of both polymers. Since polarity force and hydrogen-bonding force components typically do not contribute much to the total Hildebrand value of a polymer, those polymers with lower dispersion force usually have lower surface tensions. Therefore, it may be desirable to choose an overcoat solvent that has a lower dispersion force than that of the basecoat solvent.

According to embodiments of the present invention, it may be desirable to select a solvent for each polymer in the multi-layered sequence before proceeding with any polymer film deposition. A solvent selected for an underlying layer may affect the selection of solvents for the subsequent layers. And an underlying layer may be subject to the solvents for all the subsequent layers. Therefore, it may be desirable to coordinate the selection of solvents for all the polymer layers in the multi-layered sequence. According to an embodiment of the present invention it may be desirable to carry out individual film-on-film coating experiments to verify the selection of solvents.

At step 110, each polymer layer may be deposited from its selected solvent onto a preceding layer. An overcoat polymer may be dissolved in its selected solvent and deposited onto an undercoat with a spin casting process. A relationship among polymer solution concentration, spin rate and film thickness may be determined for each polymer prior to the spin casting process. The deposition process may be followed by a heat curing process and/or a UV cross-linking process. At the end of step 110, discrete layers of polymers in a desired sequence may be obtained. Due to the differential solubility of the selected solvents, preferably none of the polymer layers is dissolved and they may have uniform coverage on one another. In order to precisely measure and control the multi-layered structure, it may be desirable to deposit on one or more test substrates a control film for each polymer layer, using the same polymer solution. After the multi-layered structure has been formed, its overall thickness may be compared to the sum of the control film thicknesses to evaluate discreteness and uniformity of the polymer layers.

At step 112, a cathode and/or other layers in the multi-layered electro-optic device may be formed. For example, a cathode layer may comprise one or more low work function metals such as magnesium (Mg), calcium (Ca), silver (Ag), sodium (Na), potassium (K), aluminum (Al), or alloys thereof. It may be deposited onto the existing multi-layered stack. Other layers of materials necessary to complete the device may also be added.

At step 114, the exemplary method ends after a multi-layered device has been made. As stated earlier, the multi-layered device may be a light emitting device, a photovoltaic device or a photo-detector, for example. The exemplary embodiments of the present invention described above, especially the methodology for selecting suitable solvents based on differential solubility of polymers, may be adapted to manufacture these and other devices incorporating a multi-layered polymer structure.

According to embodiments of the invention, the above described method may not only enable manufacture of multilayered devices, but also improve their physical features. For example, nano-dimensional multi-layered films, with individual film layers less than 100 nanometers thick, may be incorporated in an OLED. These nano-dimensional multi-layered films may possess dielectric mirror properties as a result of the discrete interfaces formed. In addition, these discrete interfaces can also exhibit lower interfacial resistance compared to roughened, non-discrete interfaces, and therefore are typically capable of better electrical performance than those from other multi-layering processes.

### EXAMPLE 1

FIG. 2 illustrates a solubility graph for a first blue emissive polyfluorene (BEPF1) according to an exemplary embodiment of the invention. Solubility observations (soluble, partially soluble, swelling and insoluble) were based on experiments incorporating 5% solids at room temperature (22° C.) for the BEPF1. The data were plotted in the Teas graph as shown in FIG. 2, wherein the graph points are different solvents as defined by their fractional solubility parameters. The color code denotes the observation of relative solubility. A solubility window for a polymer is described by the region where the polymer exhibits solubility or partial solubility. The solubility window for the BEPF1 was roughly identified by 65<f_{d}<82, 10<fₚ<35 and 0<fₕ<25, where f_{d}, fₚ and fₕ represent the fractional contribution of dispersion force, polarity force and hydrogen-bonding force, respectively, to the overall Hildebrand parameter of a solvent.

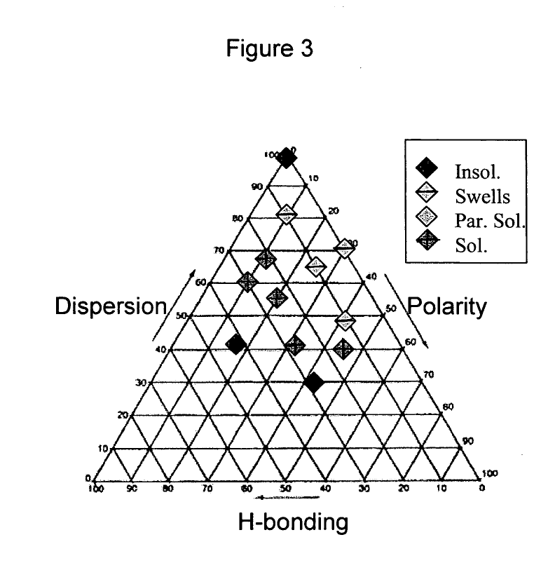

FIG. 3 illustrates a solubility graph for another polymer according to an exemplary embodiment of the invention. The polymer was polymethylmethacrylate-co-9methylanthracene methacrylate (PMMA-co-9MAMA), a PMMA-copolymer synthesized with methylmethacrylate and 9-methylanthracenyl methacrylate. Its solubility window was mapped out in the Teas graph as shown in FIG. 3. It was observed that PMMA-co-9MAMA is soluble within the region defined by 40<f_{d}<70, 10<fₚ<45 and 15<fₕ<30. Outside the region, swelling and insolubility were noted.

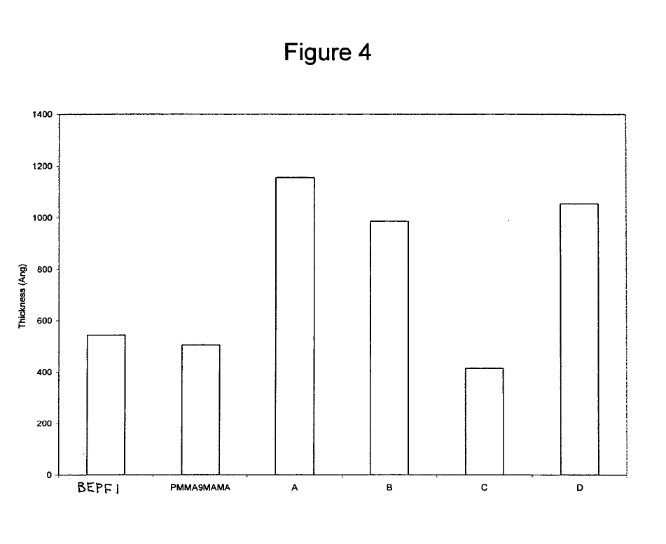

FIG. 4 illustrates the result of a film-on-film coating experiment according to an exemplary embodiment of the invention. Based on the solubility graphs shown in FIGS. 2 and 3, a film-on-film coating experiment was performed using the BEPF1 of FIG. 2 and PMMA-co-9MAMA of FIG. 3 and the results are shown in FIG. 4. With the methodology described in connection with FIG. 1, it was determined that the solubility of PMMA-co-9MAMA meets the solubility qualifications for a suitable overcoat on the BEPF1 of FIG. 2. Xylene was selected as a solvent for depositing the BEPF1 and glyme was selected as a solvent for depositing PMMA-co-9MAMA on the BEPF1, based on consideration of the solubility information shown in FIG. 2 and FIG. 3.

In the experiment, a 1% xylene solution of the BEPF1 was spun cast onto quartz at 2000 RPM, resulting in a control film 544 angstroms (Å) thick (column BEPF1 in FIG. 4). A 1% glyme solution of PMMA-co-9MAMA was also spun cast, resulting in a control film 505 Å thick (column PMMA9MAMA in FIG. 4). Quartz samples A, B, and D were also spun cast with the 1% xylene solution of the BEPF1 and then further coated with the 1% glyme solution of PMMA-co-9MAMA. Profilometry data of the resulting samples showed the films were 1155 Å, 986 Å, and 1054 Å thick (column A, B and D in FIG. 4), respectively. An inverse coating test was also performed wherein a film was cast from the 1% glyme solution of PMMA-co-9MAMA and further coated with the 1% xylene solution of the BEPF1. The resulting film, C, was only 415 Å (column C in FIG. 4). The inverse coating test revealed that the BEPF1 likely possesses a higher surface tension than PMMA-co-9MAMA. In view of the fact that the film thickness in samples A, B, and D are substantially the same as the sum of the control film thicknesses and the BEPF1 is insoluble in glyme, it is reasonable to infer discrete film-on-film formation of PMMA-co-9MAMA over the BEPF1. This film-on-film coating experiment demonstrated formulation of polymeric solutions of PMMA-co-9MAMA useful in casting discrete multiple layers on the BEPF1. These discrete multi-layers may contain red emissive materials that receive triplet energy from the blue emissive sub-layers that further emit the lower energy light, a strategy towards improved device power efficiency.

### EXAMPLE 2

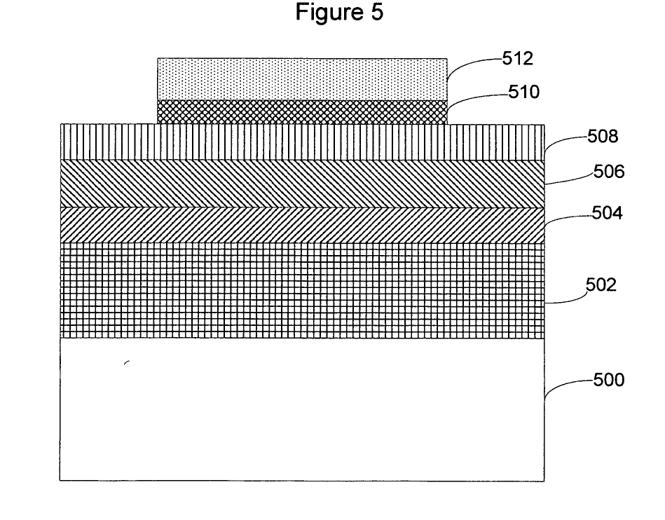

FIG. 5 illustrates a cross-sectional view of a multi-layered polymer light emitting device according to an exemplary embodiment of the invention.

A polymer light emitting device (PLED) was successfully fabricated utilizing the multi-layer approach described above. Two polymer layers were sequentially spun cast from solution to create a bi-layer, solution-processed PLED. An indium-tin-oxide (ITO) 502 coated glass substrate 500 was cleaned using solvents. Upon further ultraviolet ozone treatment, PEDOT was spun onto the substrate at 5000 RPM to form a PEDOT layer 504 approximately 700 Å thick. After baking the substrate at 170° C. for one hour, an emissive polymer layer 506 comprising a second blue emissive polyfluorine (BEPF2) approximately 700 Å thick was spun on. This was followed by an approximately 200Å-thick KL-22 (a polymethylmethacrylate co-polymer containing 1% Polyfluor™ 394 available from Polysciences, Inc.) layer 508, a resistive energy transport layer, spun cast from glyme at 3000 RPM. A control film for the effect of solvent treatment with pure glyme was spun on as well as a control film for the effect of ethyl acetate:dimethylformamide (DMF). A cathode of sodium fluoride (NaF) 510 and aluminum (Al) 512 was then fabricated using standard CVD procedures. The operating voltage of the device incorporating the multi-layer was about six volts higher than a single layer device incorporating the BEPF2, as expected. It is believed that the higher operating voltage is not due to the fabrication process, but rather due to the low electron mobility of KL-22.

### EXAMPLE 3

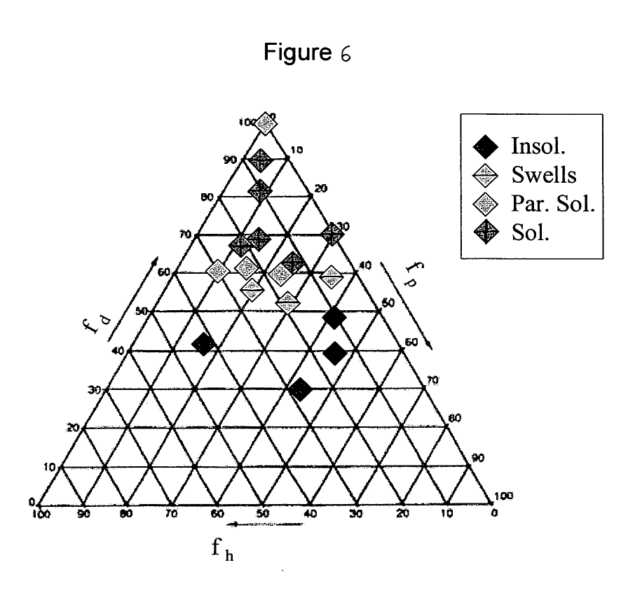

FIG. 6 illustrates a solubility graph for a third blue emissive polyfluorine (BEPF3) according to an exemplary embodiment of the invention. Solubility observations (soluble, partially soluble, swells, insoluble) were based on experiments incorporating 10% solids at room temperature (22° C.) for the BEPF3. The data were plotted according to the Teas method.

As can be seen, a boundary region exists at about f_{d}=60. Below that value swelling and insolubility are noted. The region closest to the solubility boundary should prove to be a region of strong attraction and therefore high adhesion. This region is best described by the coordinates: 45<f_{d}<60, 15<fₚ<40, 0<fₕ<40. Outside those coordinates, multi-layering attempts likely would lead to blending (f_{d}>60) or poor adhesion (f_{d}<45). It is further noteworthy that the location of the boundary region is expected to be temperature dependent (high temperatures lower the boundary, lower temperatures raise it).

A pinhole free film of the BEPF3 was deposited onto a glass slide from a 10% cumene solution measuring 1.65 μm in thickness (control sample). A pinhole free film of Benzil-endcapped PEG 5000 monomethyl ether was deposited onto a second glass from a 10% solution in chloroform-acetonitrile (50:50) measuring 0.75 μm in thickness. A third glass slide was coated with a pinhole free film of the BEPF3 and then over-coated with a film of BPEG, the slide was scratched and the total thickness was 2.1 μm, consistent with the sum of both films. The results indicate that formulation of compatible polymer over-coatings on the BEPF3 are possible within the region defined by the 3-D coordinates: 45<f_{d}<60, 15<fₚ<40, 0<fₕ<40.

### EXAMPLE 4

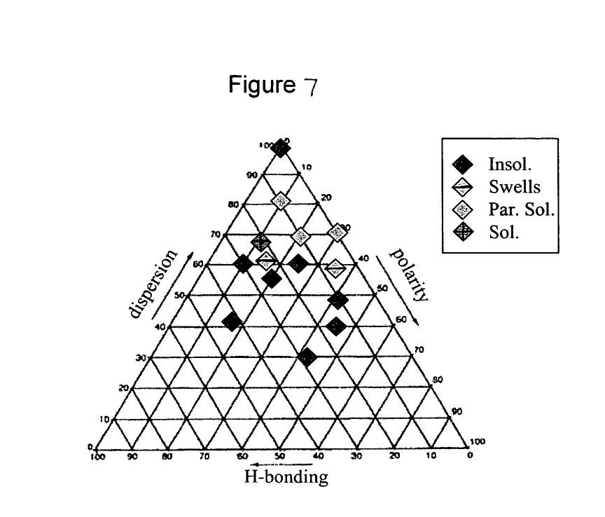

FIG. 7 illustrates a solubility graph for another light emissive polymer according to an exemplary embodiment of the invention. This light emissive polymer is ADS-329® (purchased from American Dye Source, Inc.), another blue-emissive polyfluorene. Solubility observations (soluble, partially soluble, swells, insoluble) were based on experiments incorporating 5% solids at room temperature (22° C.) for ADS-329®. The data were plotted according to the Teas method. As can be seen, a finite solubility window was observed for ADS-329®. The window is best described by the 3-D coordinates: 65<f_{d}<82, 10<fₚ<35, 0<fₕ<25. Outside this region, swelling and insolubility of ADS-329® were noted.

While the foregoing description includes many details and specificities, it is to be understood that these have been included for purposes of explanation only, and are not to be interpreted as limitations of the present invention. It will be apparent to those skilled in the art that other modifications to the embodiments described above can be made without departing from the spirit and scope of the invention. Accordingly, such modifications are considered within the scope of the invention as intended to be encompassed by the following claims and their legal equivalents.

1. A method for making a multi-layered device, the method comprising:
determining a desired sequence of two or more polymers in a multi-layered device;
for each of the two or more polymers in the desired sequence, identifying a solubility window in a solubility graph, and selecting a solvent based on the solubility window such that the
solvent does not dissolve a preceding polymer in the desired sequence;
depositing each of the two or more polymers from its selected solvent; and
forming a multi-layered device having the two or more polymers in the desired sequence.

2. The method according to claim 1, wherein the multi-layered device is a light emitting device.

3. The method according to claim 1, wherein the multi-layered device is a photovoltaic device.

4. The method according to claim 1, wherein the two or more polymers comprise at least one light emissive polymer or charge transport polymer.

5. The method according to claim 1, wherein each of the two or more polymers has a smaller surface tension than a preceding polymer in the desired sequence.

6. The method according to claim 1, wherein the solubility graph is a Teas graph.

7. The method according to claim 1, wherein the step of depositing each of the two or more polymers comprises spin-casting each of the two or more polymers from its selected solvent.

8. A multi-layered device, the device comprising:
a substrate;
a first electrode;
a second electrode; and
two or more polymers in a predetermined sequence located between the first electrode and the second electrode, wherein each of the two or more polymers is deposited from a solvent that does not dissolve a preceding polymer in the predetermined sequence.

9. The device according to claim 8, wherein the multi-layered device is a light emitting device.

10. The device according to claim 8, wherein the multi-layered device is a photovoltaic device.

11. The device according to claim 8, wherein the two or more polymers comprise at least one light emissive polymer or charge transport polymer.

12. The device according to claim 8, wherein each of the two or more polymers has a smaller surface tension than a preceding layer of polymer in the predetermined sequence.
